(19) United States
(12) Patent Application Publication
(10) Pub. No.: US 2025/0044833 A1
(43) Pub. Date: Feb. 6, 2025

(54) HEAD-MOUNTED DISPLAY

(71) Applicant: Apple Inc., Cupertino, CA (US)

(72) Inventors: Paul X. Wang, Cupertino, CA (US); Jeremy C. Franklin, San Francisco, CA (US)

(21) Appl. No.: 18/365,442

(22) Filed: Aug. 4, 2023

(51) Int. Cl. G06F 1/16; H05K 7/20

(52) U.S. Cl. CPC G06F 1/163; H05K 7/20972

(57) ABSTRACT

A cartridge including a housing, a processor positioned within the housing to provide video output to a display unit of a head-mounted display (HMD), and an attachment interface configured to removably attach the cartridge to the display unit.

### FIELD

The described embodiments relate generally to electronic devices having removable components. More particularly, the present embodiments relate to a head-mountable device having deployable processing cartridge.

### BACKGROUND

Head-mountable displays (HMDs) are developed to be comfortably worn for extended periods of time. The ever increasing desire to improve performance, functionality, and battery life of HMDs results in a device that includes several electrical components, each of which add weight to the system. There is a constant balance between maximizing user comfort while maintaining or excelling the performance and functionality of the device. Unbalanced weight distribution experienced by a user while wearing the head-mountable display, particularly weight distributed in front of the user's face, can negatively impact the user's experience. Thus, there is a need for a light-weight HMD assembly that does not sacrifice performance or functionality.

Further, the desire to improve functionality and performance while reducing the form factor of the device creates a challenge of properly cooling or ventilating the device. Accordingly, there is a need to more efficiently dissipate heat from the HMD.

### SUMMARY

According to some aspects of the present disclosure, a cartridge can include a housing, a processor positioned within the housing to provide video output to a display unit of a head-mounted display (HMD), and an attachment interface to removably attach the cartridge to the display unit.

In some examples, the cartridge can include a battery positioned within the housing to power the HMD, and a cable electrically connecting the cartridge to the HMD. The cartridge can be removably inserted into a slot defined by the HMD. The attachment interface can removably attach the cartridge within an internal volume of the display unit. The cartridge can include a fan, wherein, when the cartridge is attached to the HMD, the fan can be positioned proximate a component disposed in the internal volume of the HMD to provide an airflow to the internal volume.

In some examples, the attachment interface can include at least one of a mechanical coupler or a magnetic coupler. The attachment interface can include a push-push mechanism. The cartridge can include a user input interface to receive a user input.

According to some aspects, a head-mountable assembly can include a processor and a display unit defining a slot to receive the processor. In a first mode, the processor can be positioned within the slot to provide image data to the display unit. In a second mode, the processor can be removed from the slot and provide image data to the display unit.

In some examples, the processor can be positioned adjacent to a display screen of the display unit in the first mode. In the second mode, the processor can be secured to a retention band of the display unit. The head-mountable assembly can include a coupler to releasably secure the processor in the slot. The head-mountable assembly can include a biasing element to selectively retain the processor in the display unit. The head-mountable assembly can include a cable electrically connecting the processor and the display unit in the second mode. The head-mountable assembly can include a first electrical connector positioned in the slot to engage a second electrical connector on the processor in the first mode.

According to some aspects, an electronic component for a head-mountable device can include an input to receive a user input, and a central processing unit (CPU) of the head-mountable device. The electronic component is configured to be selectively carried by the head-mountable device.

In some examples, the input can include at least one of a button, a touchpad, or an analog stick, or a D-pad. The electronic component can include a haptic engine. The electronic component can be attachable to the head-mountable device. The electronic component can include a motion sensor to provide user feedback to the CPU. The electronic component can include a battery, wherein the battery can be a primary power source of the head-mountable device.

### BRIEF DESCRIPTION OF THE DRAWINGS

The disclosure will be readily understood by the following detailed description in conjunction with the accompanying drawings, wherein like reference numerals designate like structural elements, and in which:

FIG. 1A shows a top view of a head-mountable display assembly.

FIG. 1B shows a side view of a head-mountable display assembly with multiple cartridge locations.

FIG. 2 shows a schematic block diagram of a head-mountable display assembly.

FIG. 3 shows a cross-sectional side view of a cartridge.

FIG. 4 shows a front view of a head-mountable display assembly.

FIG. 5 shows side view of a head-mountable display assembly.

FIG. 6 shows a side cross-sectional view of a head-mountable display assembly including a deployable cartridge.

FIG. 7 shows a perspective view of a cartridge including input elements.

FIG. 8A shows a side view of a foldable cartridge in a folded state.

FIG. 8B shows a side view of the foldable cartridge of FIG. 8A opening.

FIG. 8C shows a side view of the foldable cartridge of FIGS. 8A and 8B in an open state.

FIG. 9 shows a top cross-sectional view of a cartridge including fans.

FIG. 10 shows a top view of a cartridge including vents.

FIG. 11 shows a tope view of a cartridge including vents.

FIG. 12 shows a front view of a head-mountable display assembly including a cable management system.

FIG. 13 shows a side cross-sectional view of a head-mountable display assembly including a cable management system.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The desire to improve performance, functionality, and battery life of HMDs results in a device that can include several heavy electrical components, which can impact the ability to maintain user comfort. Ensuring user comfort is a challenge of conventional HMDs. Thus, there is a need for a light-weight HMD assembly that does not sacrifice performance or functionality.

The present systems and methods provide an HMD with a removable or deployable cartridge. The cartridge can include one or more electronic components of the HMD. For example, the cartridge can include at least one of a processor, a battery, memory, sensors, or fans of the HMD. In some examples, the cartridge can be referred to as a processing cartridge, a puck, an accessory, an electronic accessory, or a processor. As used herein, “cartridge” can refer to any container, enclosure, or housing that carries components and is made ready for insertion into or attachment on an HMD.

In some examples, the cartridge can include a housing to contain the various components of the cartridge. The housing can be made from metal, plastic, or any other suitable material to protect and house electronic components. A processor can be contained within the internal volume defined by the housing. As used herein, “processor” can refer to any number of computing components capable of executing or carrying out the instructions of a computer program. For example, “processor” can refer to a single or multi-core processors, specialized processors, or any other controller capable of executing instructions. In some examples, “processor” can refer to a central processing unit or the main or primary processor used by the electronic device. In some examples, the processor can provide video output to an HMD. Thus, the cartridge can housing the main, and in some examples the only, processor for the HMD, despite being separable from the HMD.

In some examples, the cartridge can weigh approximately 100-150 grams. The cartridge can account for approximately 25-30% of the weight of the assembly. Thus, removing the cartridge from the HMD can greatly enhance wearer comfort, even over extended periods of time.

The cartridge can be housed, attached, mounted, or otherwise carried by the HMD. As used herein, “HMD assembly”, “assembly”, or system can refer to the HMD (i.e., display unit) and the cartridge, regardless of whether the cartridge is attached or deployed from the HMD. The HMD assembly can include an attachment interface to removably connect the cartridge and the HMD. The attachment interface can include features present on both the cartridge and the HMD. In some examples, the attachment interface is solely on the cartridge or the HMD and engages with parts of the other to attach.

The attachment interface can include any suitable connector, fastener, belt, strap, magnet, Velcro, snap, friction fit, or any other suitable system for removably attaching the cartridge on or in the HMD. In some examples, the attachment interface is disposed in a slot defined by the HMD and sized/shaped to receive the cartridge. In some examples, the slot itself acts as the attachment interface.

The HMD can include a housing that at least partially forms a slot, a hole, a cavity or a recess to receive the cartridge. As used herein, a “slot” can refer to any hole, gap, cavity, recess, or depression and is not limited to any particular geometry. The cartridge can sit in the slot and can be removed as desired by the user. Thus, the HMD assembly can include multiple configurations or modes. In a first mode, the cartridge can be positioned within the slot. While the cartridge is positioned in the slot, the cartridge can provide image data to the HMD via a cable connection or a direct electrical connection. In a second configuration, the cartridge can be removed from the slot. When removed from the slot, the cartridge can still provide image data to the HMD via a wired or wireless connection. When removed, the cartridge can be positioned in many different convenient locations. For example, the cartridge can be held by the user, placed in a pocket, placed on a table or desk, attached to the HMD retention band, and the like.

Further, the desire to improve functionality and performance while reducing the form factor of the device creates a challenge of properly cooling or ventilating the device to prevent overheating. Accordingly, there is a need to more efficiently dissipate heat from the HMD. The deployable cartridge can advantageously reduce heat within the system by including one or more on-board fans to cool the internal volume of the cartridge and/or the internal volume of the HMD. Further, when the cartridge is removed from the HMD, the internals of the HMD can more efficiently dissipate heat through the volume of the cavity left by removed the cartridge.

In some examples, the cartridge can include one or more input elements for the user to provide input to the HMD. In other words, the cartridge can include a remote controller or other input functionality for the HMD. Thus, the cartridge can include the CPU for the controller, the power source for the HMD, and also include input elements for the HMD, all while not being integrally or structurally attached to the HMD.

The cartridge can include a wide range of sensors in order to detect the environment of the cartridge. The sensors on the cartridge can include visual sensors, thermal sensors, motion sensors, light sensors, force sensors, moisture sensors, audio sensors, capacitive sensors, and the like.

The HMD assembly can include one or more cartridges. In some examples, the assembly includes a primary cartridge (e.g., mother device), and a secondary or companion cartridge (e.g., child device). The primary cartridge and the secondary cartridge can communicate via Bluetooth or any other wireless or wired communication protocol. In some examples, both the primary cartridge and the secondary cartridge can be attached to, or inserted into, the HMD. In some examples, the primary cartridge and the secondary cartridge can be attached to each other before being integrated with the HMD. In some examples, the primary cartridge and the secondary cartridge can be independently integrated with the HMD (i.e., separate from each other).

In some examples, the cartridge can include a projector to project a virtual keyboard onto a surface in front of the user. The user can then interact with the virtual keyboard to provide input to the HMD. The cartridge can further include sensors to detect and determine the input received via the virtual keyboard.

In some examples, the cartridge can include a triangulated IMU system that can use sensor fusion with visual inputs to detect inputs on the virtual keyboard. Visual sensors from the HMD can be combined with sensors from the cartridge to generate the virtual keyboard.

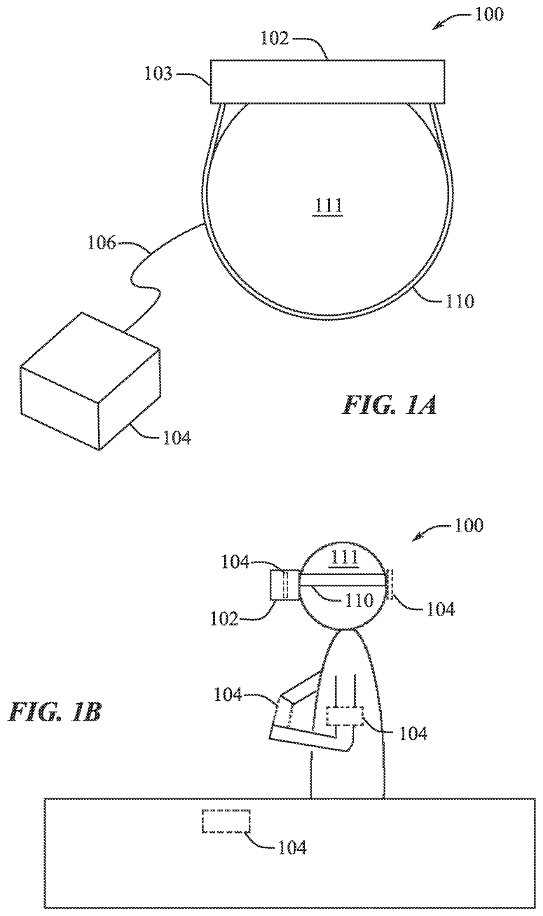

These and other embodiments are discussed below with reference to FIGS. 1-13. However, those skilled in the art will readily appreciate that the detailed description given herein with respect to these Figures is for explanatory purposes only and should not be construed as limiting. Furthermore, as used herein, a system, a method, an article, a component, a feature, or a sub-feature comprising at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option).

FIG. 1A shows a top view of a head-mountable assembly 100. The assembly 100 can include an HMD 102 (also referred to herein as a “display” or “display unit”), a retention band 110, and a cartridge 104 electrically connected to the HMD 102 by a wire or a cable 106.

The HMD 102 can include a display (not shown in FIG. 1A) and a frame or housing 103 of the HMD 102 attached to the display. In some examples, the display includes an opaque, translucent, transparent, or semi-transparent screen, including any number lenses, for presenting image data. The housing 103 can at least partially border one or more edges of the display. In some examples, the housing 103 can be configured to contact a user's face or head 111. In some examples, the housing 103 blocks outside light and limits the peripheral view of the user. Various components of the HMD 102 can be positioned and secured within the housing 103. For example, the hardware and electronics which allow for functionality of the HMD 102 can be housed within the housing 103.

The assembly 100 can be worn on the user's head 111 such that the HMD 102 is positioned over the user's face and disposed over one or both of the user's eyes. The HMD 102 can be connected to the retention band 110. In some examples, the retention band 110 can be positioned against the sides and back of a user's head 111 and in contact therewith. In some examples, the retention band 110 can be at least partially positioned above the user's ear or ears. In some examples, the retention band 110 can be positioned adjacent to the user's ear or ears. The retention band 110 can extend around the user's head 111. In this way, the HMD 102 and the retention band 110 can form a loop that can retain the assembly 100 on the user's head 111. It should be understood, however, that the configuration illustrated in FIG. 1A is just one example of how the components of a modular wearable device can be arranged, and that in some examples, a different number of connector straps and/or retention bands can be included.

In some examples, the cartridge 104 can include the primary controller or processor relied on by the HMD 102 to operate. In some examples, the cartridge 104 can include the only processor for the HMD assembly 100. The cartridge 104 can, in some examples, include the main logic board (MLB) for the HMD 102. The cartridge 104 can include a battery that provides power to the HMD 102 via a cable 106. In some examples, the cartridge can be power an 8-12 watt system, or one with higher or lower power demands. In some examples, the cable 106 can establish a data or communications link between the HMD 102 and the cartridge 104. Further details regarding the HMD assembly 100 is described below with reference to FIG. 1B.

Any of the features, components, and/or parts, including the arrangements and configurations thereof shown in FIG. 1A can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 1A.

FIG. 1B shows a side view of the HMD assembly 100 showing the cartridge 104 in multiple possible locations and configurations. An advantage of the disclosed deployable cartridge 104 is the ability to position the cartridge 104 where desired by the user 111. According to various embodiments described herein, the cartridge 104 can be removed from the HMD 102 which can substantially reduce the weight of the HMD 102 on the user's head 111. FIG. 1B illustrates example locations for the cartridge 104 in dashed lines. The cartridge 104 can be communicatively coupled to the HMD via a wired or wireless connection. For clarity, the cable 106 is not shown in FIG. 1B. However, it will be understood that in each of the possible configurations, the cartridge 104 can be electrically connected to the HMD by the cable 106 or wirelessly.

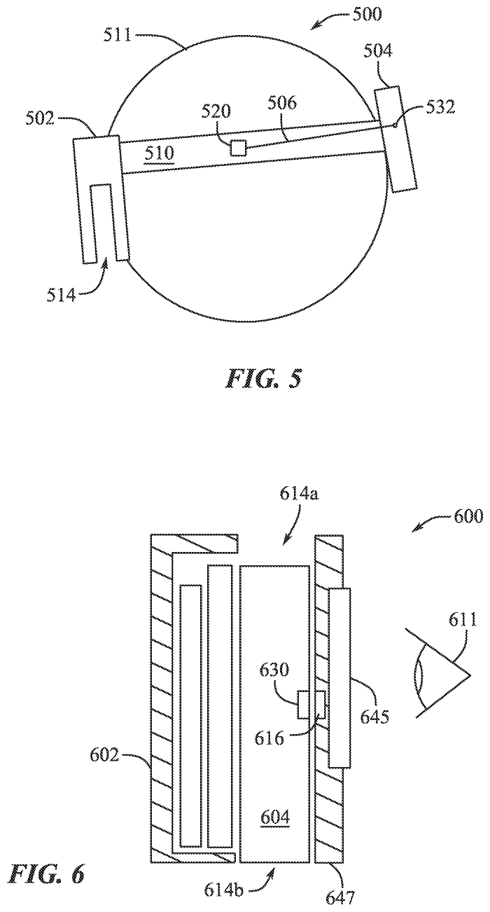

In some examples, the cartridge 104 can be removed from the HMD 102 and positioned or attached to the retention band 110. This configuration is discussed in greater detail with reference to FIG. 5.

In some examples, the cartridge 104 can be attached to, or can be carried by, a portion of the user's body. For example, the cartridge 104 can be attached to an arm band worn by the user. In some examples, the cartridge can be worn like a necklace, belt attachment, fanny pack, or any other wearable accessory. In some examples, the cartridge 104 can be sized and shaped to fit into a user's pants pocket.

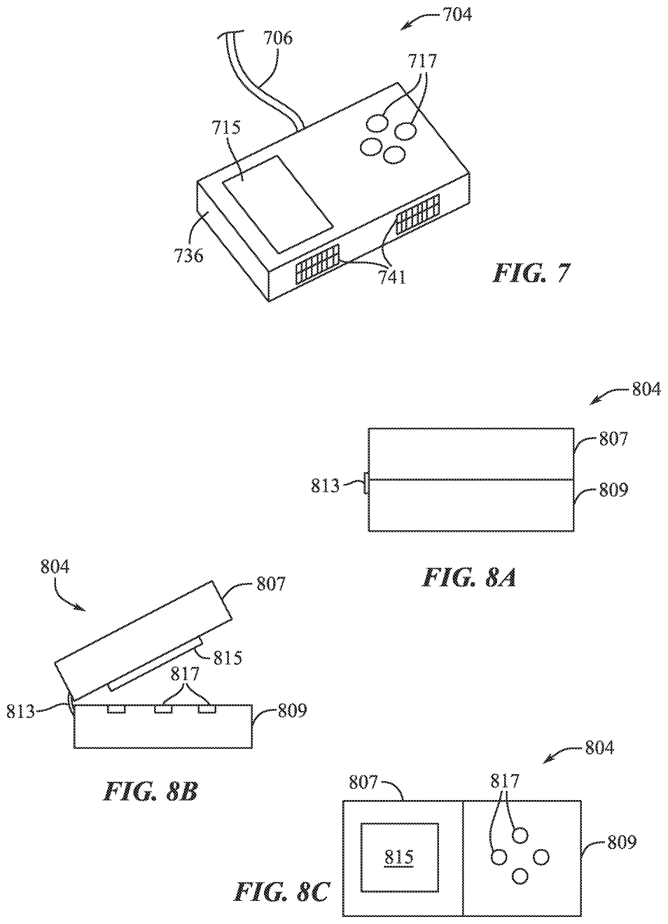

In some examples, the cartridge 104 can be set or placed on any suitable object, such as a table, a desk, a seat, a couch, or the floor. As is described in greater detail with reference to FIGS. 7-8C, the cartridge 104 can be used as an input device. Thus, in some examples, the cartridge 104 can be released from the HMD 102 and held by the user, similar to a remote controller.

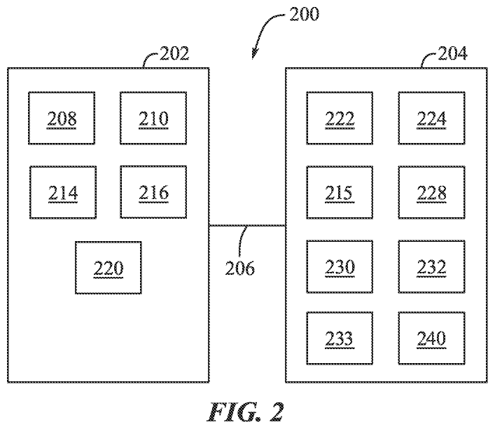

The cartridge 104 can be inserted into a slot or opening defined by the HMD 102. In some examples, the cartridge 104 can be mounted or attached to an external surface of the HMD 102. For example, the cartridge 104 can be attached to a front exterior surface of the HMD 102, such that the cartridge 104 defines an exterior of the HMD 102 when attached to the HMD 102. Further details regarding HMD assemblies are described below with reference to FIG. 2.

The cartridge 104 can be a companion device that communicates with the HMD 102 via a communications link. The communications link can be a physical connection, such as an electrical wire, or can be a wireless connection, such as Bluetooth, WI-Fi, proximity sensors, etc.

Any of the features, components, and/or parts, including the arrangements and configurations thereof shown in FIG. 1B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 1B.

FIG. 2 shows a schematic block diagram of an HMD assembly 200. The HMD assembly 200 can be substantially similar to, including some or all of the features of, the assemblies described herein, including assembly 200.

It will be understood that only select components are shown and described in FIG. 2 for simplicity. The assembly 200 is not limited to these components and may include additional components not shown or described herein.

The assembly 200 can include a display unit or HMD 202 and a cartridge 204 electrically connected to the HMD 202 via a cable 206. In some examples, the HMD 202 and the cartridge 204 can communicate wirelessly. The assembly 200 can be modular (i.e., the HMD 202 and the cartridge 204 can be attachable and detachable from one another), as opposed to the cartridge 204 being integrally formed and configured to be permanently attached to the HMD 202. In other words, the assembly 200 can be constructed so as to easily remove the cartridge 204 from the HMD 202 at will.

The HMD 202 can include a display 208, a retention band 210, a slot 214 to receive the cartridge 204, a coupler 216 to physically connect with the cartridge 204, and an electrical interface 220 to electrically connect with the cartridge 204.

The display 208 of the HMD 202 can include an opaque, translucent, transparent, or semi-transparent screen, including any number lenses, for presenting image data to the wearer. The HMD 202 can include a headband or retention band 210. In some examples, the retention band 210 is a band, strap, belt, arms, or other form of support that secures the HMD 202 to a user's head.

In some examples, the HMD 202 includes a first coupler or attachment interface 216 that engages, attaches to, or couples with the cartridge 204. The first coupler 216 can releasably couple with the cartridge 204. As described in greater detail below, the first coupler 216 can include any suitable attachment mechanism for connecting to the cartridge 204. The first coupler 216 can be a mechanical and/or magnetic attachment interface. In some examples, the first coupler 216 is a recess or slot defined by the cartridge 204 that receives and releasably secures the cartridge 204. In some examples, the cartridge can be retained within the recess or slot via an interference fit, detent features, magnetic interaction, or combinations thereof.

As described herein, the cartridge 204 can include one or more electronic components required by the HMD 202. For examples, the cartridge 204 can include a processor 222 and a battery 224. In some examples, the cartridge 204 can include a battery 224. The battery 224 can be a primary power source for the HMD 202 and/or the cartridge 204 and can operative to electrically couple with and supply power to the components of the HMD 202 and/or the components of the cartridge 204. The battery 224 can be a rechargeable battery, such as a lithium-ion polymer battery. The battery 224 can be completely or entirely positioned within a housing of the HMD 202. In some examples, the battery 224 can be a single unit or multiple batteries can be used as the main power source of the HMD 202 and/or cartridge 204.

By having the ability to remove the battery 224 from the HMD 202, larger batteries can be used than would otherwise be feasible using a permanent battery in the HMD 202. In some examples, the battery 224 is the sole or only battery used to power the assembly 200. In other examples, the battery 224 is an auxiliary or supplementary battery that can be used in conjunction with batteries on board the HMD 202 to power to assembly 200.

In some examples, the cartridge 204 can include one or more inputs 215, including but not limited to, buttons, touchpads, D-pads, analog sticks, etc. The inputs 215 can be positioned on an exterior of a housing of the cartridge 204. Upon manipulation of the inputs 215 by a user, a signal can be transmitted to the HMD 202 (e.g., via the cable 206). In some examples, the signals can be transmitted wirelessly to the HMD 202. In this manner, the cartridge 204 can function as a remote controller of the HMD 202. Further details regarding the inputs are provided below with reference to FIGS. 7-8C.

The cartridge 204 can include an electrical interface 232 to electrically couple with an electrical interface 220 of the HMD 202. The electrical interface 232 can include a plug or electrical connector for establishing an electrical connection between the cartridge 204 and the HMD 202. Specifically, the electrical interface 232 can be in electrical communication with the electrical components of both the HMD 202 and 204. Power and/or data can be transferred between the HMD 202 and the cartridge 204. The electrical interface 232 can transfer power/data from the HMD 202 to the cartridge 204 by a cable 206 or via direct connection. The electrical interface 232 can be a direct electrical connection. In some examples, the electrical interface 232 can establish an electrical connection directly with the HMD 202. In some examples, the electrical interface 232 can include a cable or wire that connects to the HMD 202.

In some examples, the cartridge 204 includes a second coupler or attachment interface 230 that engages, attached, or couples with the HMD 202. The second coupler 230 can releasably or fixedly couple with the HMD 202. As described in greater detail below, the second coupler 230 can include any suitable attachment mechanism for connecting to the HMD 202. The second coupler 230 can be a mechanical and/or magnetic attachment interface. In some examples, the second coupler 230 can engage with a recess or slot defined by the HMD 202. Further details regarding attachment interfaces and couplers are provided below.

In some examples, the cartridge 204 can include an output component 233. Although only one output component 233 is shown in FIG. 2, it will be understood that the output component 233 can include multiple physically distinct or combined outputs. The output component can include a variety of electrical components that produce an output (e.g., audio component, light module, haptic component, etc.) The output component 233 can alert the user to a status or state of the HMD 202 and/or the cartridge 204. In some examples, the output component 2233 can signal whether the cartridge 204 is connected (physically and/or electrically) to the HMD 202.

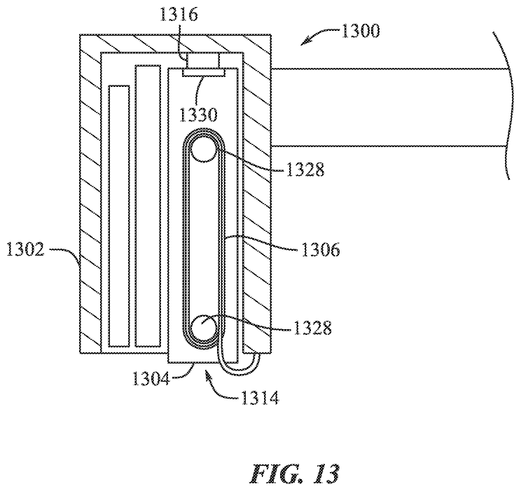

In some examples, the cartridge 204 can include a cable manager 228 (also referred to as a cable management system or cable organizer). The cable manager 228 can organize, retain, or otherwise secure the cable 206 of the assembly 200. The cable can be long, in order to accommodate for instances when the accessory is not proximate the HMD 202 (i.e., not in the cartridge 204). The length of the cable can interfere with use of the HMD 202. Thus, the cable manager 228 can be used to orderly retain and store the cable 206. Cable management systems are discussed in greater detail below with reference to FIGS. 12-13.

In some examples, the cartridge 204 can include a sensor unit 240. The sensor unit 240 can detect or determine one or more aspects of the operational environment or physical environment of the assembly 200. Although only one sensor unit 240 is shown in FIG. 2, it will be understood that the sensor unit 240 can include multiple physically distinct or combined sensors. For example, sensor unit 240 can include one or more of a contact sensor, a pressure sensor, a proximity sensor, a camera, a microphone, an infrared receiver, a global positioning system unit, a gyroscopic sensor, an accelerometer, a capacitive sensor, a biometric sensor, a magnetometer, a radar unit, a LIDAR unit, an ultrasound unit, a temperature sensor, or any other sensor capable of detecting or determining one or more aspects or conditions of the operational environment of the assembly 200.

In a specific example, the sensor unit 240 can determine whether the cartridge 204 is near or attached to the HMD 202. The sensor unit 240 can be operatively coupled to the cartridge 204 to cause the cartridge 204 to perform one or more actions. For example, upon determining that a user is attempting to attach the cartridge 204 to the HMD 202, the sensor unit 240 can produce a signal that triggers the first coupler 214 to attach to the cartridge 204. In some examples, the cartridge 204 includes an actuator that reacts to placement of the cartridge 204 in/on the mount, causing the first coupler 214 to secure the cartridge 204.

Any of the features, components, and/or parts, including the arrangements and configurations thereof shown in FIG. 2 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 2.

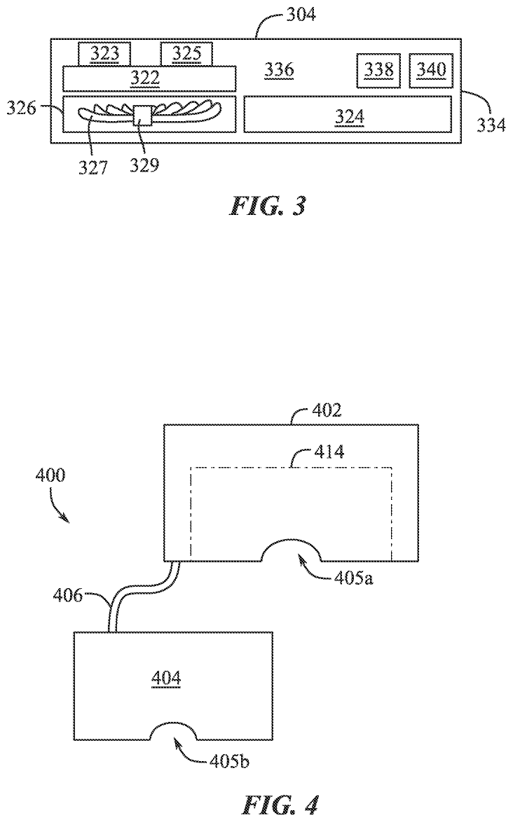

FIG. 3 shows a cross-sectional side view of a cartridge 304. The cartridge 304 can be substantially similar to, including some or all of the features of, the cartridges described herein, including cartridges 104 and 204. The cartridge 304 can be removably attachable to an HMD.

The cartridge 304 can include one or more electronic components disposed within an internal volume 336 defined by the housing 334. For example, the cartridge 304 can include a processor 322 and a battery 324 disposed or positioned within the internal volume 336 defined by a housing 334 of the cartridge 304. In some examples, the cartridge 304 includes a fan 326 positioned within the internal volume 336. The fan 326 can include one or more blades 327 driven by a motor 329 to produce airflow to lower the temperature of the internal volume 336. As described in greater detail below, the fan 326 can be used to dissipate heat from one or both of the cartridge 304 and the HMD. In some examples, the cartridge 304 can include an integrated circuit 323, such as a system-on-chip (SOC). The cartridge 304 can include a memory 325, such as NAND flash memory or any other suitable storage component.

In some examples, the cartridge 304 can include a haptic component 338 positioned within the internal volume 336 of the cartridge. The haptic component 338 can produce a haptic or tactile feedback to the user. The haptic component 338 be a haptic actuator and can produce haptic feedback to be felt by the head and/or hands of the user. In some examples, the haptic component 338 can be used to generate a sound output, such as a buzz, that can be heard by the user.

In some examples, the cartridge 304 can include at least one inertial measurement unit 340 positioned within the internal volume 336. The inertial measurement unit (IMU) 340 can detect movement of the cartridge 304 and can determine a position, pose, or orientation of the cartridge 304. The inertial measurement unit 340 can include at least one of an accelerometer, gyroscope, or magnetometer. In some examples, the cartridge 304 can include multiple IMUs 340. For example, the cartridge 304 can include a first IMU positioned at a first end of the cartridge 304, and a second IMU positioned at a second, opposite end of the IMU.

Any of the features, components, and/or parts, including the arrangements and configurations thereof shown in FIG. 3 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 3.

FIG. 4 shows a front view of an HMD assembly 400. The HMD assembly 400 can be substantially similar to, including some or all of the features of, the assemblies described herein, including assemblies 100 and 200.

The HMD assembly 400 can include an HMD 402 and a cartridge 404. The HMD 402 and the cartridge 404 can be electrically coupled through a cable 406. The HMD 402 can define a recess or slot 414 defined by the housing of the HMD 402. As shown in FIG. 4, the outline of the slot 414 is depicted with dashed lines to indicate that the slot 414 is positioned in the HMD 402, for example, sandwiched between two major surfaces or faces of the HMD 402. The slot 414 can be sized and shaped to removably receive the cartridge 414. The slot 414 can have a shape the substantially matches the shape of the cartridge 414.

In some examples, the HMD 402 can include a notch or groove 405a sized, shaped, and positioned to accommodate for a user's nose. Similarly, the cartridge 404 can include a notch or groove 405b sized, shaped, and positioned to accommodate for a user's nose. The groove 405a in the HMD 402 and the groove 405b in the cartridge 404 can be substantially similar or identical, such that when the cartridge 404 is inserted into the slot 414, the grooves 405a, 405b align to allow space for the nose of the user. Additionally, the groove 405b in the cartridge 404 can be used as an orientation indicator to help the user know which way to insert the cartridge 404 into the HMD 402.

In some examples, the cable 406 can detach from HMD 402 and can be plugged into a different electronic device, such as a display, monitor, laptop, or different HMD. Thus the cartridge 404 can operate as a portable computer. In some examples, the cable 406 can be removed from the cartridge 404 and attached do a different computing element. The cable 406 can be completely removed from both the cartridge 404 and the HMD 402. For example, when the cartridge 404 is positioned in the HMD 402, electrical terminals or contacts on the cartridge 404 can electrically engage corresponding contacts in the HMD 402 to establish an electrical connection to transmit data and/or power, thereby removing the need for the cable 406. Thus, the cable 406 can be completely removed from the HMD assembly 400 when the cartridge 404 is inserted into the slot 414 of the HMD 404.

Any of the features, components, and/or parts, including the arrangements and configurations thereof shown in FIG. 4 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 4.

FIG. 5 shows a side view of an HMD assembly 500 worn by a user 511. The HMD assembly 500 can be substantially similar to, including some or all of the features of, the assemblies described herein, including assemblies 100-800. The assembly 500 can include an HMD 502, a retention band 510, and a cartridge 504.

The HMD 502 can include a slot 514 to receive the cartridge 504. The cartridge 504 can be removed or deployed from the slot 504 in order to reduce the weight of the HMD 502 of the front of the user's face. By removing the cartridge 504 from the HMD 502 greatly reduces the weight of the HMD 502 of the user's face, allowing for increased comfort and wear time.

Further, a removable cartridge 504 can be used as a counterbalance by deploying the cartridge 504 out of the HMD 502 and attaching the cartridge 504 to the retention band 510. In some examples, the cartridge 504 can be mounted to the retention band 510. For example, the cartridge 504 can be attached to the retention band 510 such that the cartridge 504 is positioned on the back of the head of the user 511. By positioning the cartridge 504 opposite the HMD 502, the center of mass of the assembly 500 can shift from the front of the user's head to the middle or center of the user's head, thereby improving weight distribution and enhancing user comfort. In some examples, the weight of the HMD 502 and the weight of the cartridge 504 is substantially similar. For example, each the HMD 502 and the cartridge 504 can weigh approximately 150 grams-300 grams.

In some examples, the retention band 510 can include an attachment interface for attaching the cartridge 504 to the retention band 510. In other words, a mount can be retrofitted onto existing retention bands without requiring modification to the existing retention bands. In some examples, the retention band 510 include a separate component for coupling with the mount. In some examples, the mount is incorporated into the retention band 510 as an integral component of the retention band 510. In some examples, the fabric of the retention band 510 secures the cartridge 504. For instance, the retention band 510 can act as a sleeve or sheath for at least some of the cartridge 504.

In some examples, the retention band 510 can include an integrated cable management system for managing a power cable 506. For example, the retention band 510 can include an electrical connector or access port 520 that can establish an electrical connection with a connector 532 of the cartridge 504. Thus, the cable 506 can establish an electrical connection between the HMD 502 and the cartridge 504. The cable 506 can be removably or permanently connected to the HMD 502 and/or the retention band 510.

In some examples, the cable 506 can be attached to, or can run along, the retention band 510 when the cartridge 504 is attached to the retention band 510. In some examples, slack from the cable 506 can be taken up using a cable management system. For instance, the retention band 510 can include hooks or holders to secure excess slack in the cable 506. The retention band 510 can include a reel or spool to wind up the cable 506.

As shown in FIG. 5, the slot 514 can be accessible from a bottom of the HMD 502. In other words, an opening or aperture is defined by the bottom of the HMD 502, such that the cartridge 504 can be inserted into the HMD 502 by pushing the cartridge 504 up into the slot 514. Likewise, to eject the cartridge 504 from the HD 502, the cartridge 504 is released to travel downward (as oriented in FIG. 5). The eject or release from the slot 514, the cartridge 504 can either rely solely on the downward gravitation force, or a biasing element, such as a spring, can assist in ejecting the cartridge 504 from the slot 514. In some examples, the biasing element can selectively retain the cartridge 504 in the slot 514. In other words, the biasing element can selectively bias the cartridge 504 into the slot 514 or out of the slot 514 as needed. As shown as described herein, other configurations for inserting and ejecting a cartridge from an HMD are possible, including but not limited to a slot located on the side of the HMD or a slot located on the top of an HMD.

In some examples, the slot 514 allows for the HMD 502 to cool without the help of fans. Many conventional HMDs require on-board fans, which increases the overall thickness and weight of the device. A typical system's thermals are too high to operate in steady state touch conditions without a fan. The maximum temperature of the system components can be exceeded without the use of a fan on a conventional HMD. However, by providing the slot 514 in the HMD 502 there is much greater cooling of the system by allowing the heat to better dissipate away from the internal components via the slot 514. Thus, with the cartridge 504 removed from the HMD 502, there is no need for a fan on-board the HMD 504. Further, as described herein, when the cartridge 504 is in the HMD 502, the cartridge 504 can include on-board fans to help reduce heat within the cartridge 504 and the HMD 502. Further details regarding HMD assemblies are described below with reference to FIG. 6.

Any of the features, components, and/or parts, including the arrangements and configurations thereof shown in FIG. 5 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 5.

FIG. 6 shows a side cross-sectional view of an HMD assembly 600 including a deployable cartridge 604. The HMD assembly 600 can be substantially similar to, including some or all of the features of, the assemblies described herein, including assembly 100, 200, 400 and 500.

In some examples, the HMD assembly 600 can include a display 645 to provide visual output to a user's eye 611. The display 645 can be located between the cartridge 604 and the user's eye 611 when the cartridge 604 is positioned in the HMD 602.

The HMD assembly 600 can include a removable or deployable cartridge 604, as described herein. The HMD 602 can include a frame or housing 647 that defines one or more openings 614a, 614b through which the cartridge 604 can be inserted into or removed from the HMD 602. For example, a first opening 614a can be located at the top of the HMD 602, as oriented in FIG. 6. By locating the opening 614a in the top of the HMD 602, the cartridge 604 is less likely to accidentally fall out of the HMD 602. In some examples, the HMD 602 can include both a top opening 614a and a bottom opening 614b. Thus, the HMD 602 can define a pass-through slot for the cartridge 604 to be selectively inserted or withdrawn from either opening 614a, 614b. In addition to providing easy and convenient access to the cartridge 604, the pass-through opening improves air flow and cooling for the HMD assembly 600.

The cartridge 604 can include a coupling member 630 to engage with a corresponding coupling member 616 on the HMD 602. In some examples, the coupling member 630 can include a magnet or magnetically attracted component located on an exterior or interior of the cartridge 604. Likewise, the coupling member 616 can include a magnet or magnetically attracted component positioned to magnetically couple with the coupling member 630 of the cartridge 604, when the cartridge is inserted into the HMD 602. In some examples, the coupling member 616 can be secured to the HMD 602, such as mounted to the housing 647. In some examples, the cartridge 604 and the HMD 602 can each include multiple magnets to secure the cartridge 604 within the HMD 602. The strength of the magnets 616, 630 can be selected or tuned to be strong enough to securely retain the cartridge 604 within the HMD 602 when experiencing typical movement of the HMD 602, yet weak enough to be overcome by a user to remove the cartridge 604.

In some examples, when inserted into the HMD 602, the cartridge 604 can be positioned or sandwiched between the display 645 and other electronic components or the front face of the HMD 602. As described herein, the cartridge 604 can include cooling fans to produce air flow to lower the temperature of the internals of the cartridge 604 and/or the internals of the HMD 602. In some examples, the cartridge 604 can be intentionally positioned to allow for ideal airflow to the internal components of the HMD 602 when inserted, and allow for ideal passive airflow or “breathing” for the HMD 602 when the cartridge 604 is removed. Further details regarding the functionality of the cartridge is described below with reference to FIG. 7.

Any of the features, components, and/or parts, including the arrangements and configurations thereof shown in FIG. 6 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 6.

FIG. 7 shows a perspective view of a cartridge 704 including input elements. The cartridge 704 can be substantially similar to, including some or all of the features of, the cartridges described herein, including cartridges 104, 204, 304, 404, 504, and 604.

The deployable cartridge described herein can include several advantageous, such as reducing the weight of the HMD on the user's head. Additionally, the cartridge, once removed, can advantageously be used as an input device for the HMD assembly. HMD's often rely on user input to operate. The user input is often provided through buttons, joysticks, touchscreens, or other input components. Positioning inputs on the headset itself can be problematic due to limited real estate and non-ideal ergonomics of inputs on the headset. Thus, a solution is to provide inputs on the removable cartridge, such that a user can handle the cartridge as a remote controller.

In some examples, a cartridge 704 can include one or more inputs, including but not limited to, buttons 717 and a touchpad 715. The inputs 715, 717 can be positioned on an exterior of a housing 736 of the cartridge 704. Upon manipulation of the inputs 715, 717 by a user, a signal can be transmitted to the HMD via the cable 706. In some examples, the signals can be transmitted wirelessly to the HMD.

In some examples, the cartridge 704 can include one or more vents 741 to allow for airflow through the interior of the cartridge 704. The vents 741 can be positioned in a predetermined location to avoid being blocked by a user's hands when held. Further, the position of the vents 741 can be intentionally positioned to not be blocked or occluded when the cartridge 704 is inserted into the HMD. In some examples, the cartridge 704 can be sized and shaped to allow for a comfortable and ergonomic feel when being held and used as a remote controller by the user. For example, the cartridge 704 can be curved or bolstered to conform to a typical user's hands. The vents 741 can include perforations or holes in the housing 736.

In some examples, the cartridge 704 can include components intended to provide feedback to the user's hands. For example, the cartridge 704 can include a haptic engine to provide haptic or tactile feedback to the user's hands. In some examples, the cartridge 704 includes IMUs which can be used to receive orientation input from the user moving the cartridge 704. For example, the user may be playing a video game using the cartridge 704 as a controller. The user could tilt the controller to the left or to the right to produce a similar result in the video game. The movement of the cartridge 704 can be detected by on board IMUs located in the cartridge 704. Further details regarding the functionality and configurations of the cartridge are described below with reference to FIGS. 8A-8C.

Any of the features, components, and/or parts, including the arrangements and configurations thereof shown in FIG. 7 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 7.

FIG. 8A shows a side view of a foldable cartridge in a folded state. The cartridge 804 can be substantially similar to, including some or all of the features of, the cartridges described herein, including cartridges 104, 204, 304, 404, 504, 604, and 704.

In some examples, the cartridge 804 can include a first portion 807 and a second portion 809. The first portion 807 can be adjustable or movable relative to the second portion 809. For example, the cartridge 804 can fold. The first portion 807 can be pivotally connected to the second portion 809 by a hinge 813. FIG. 8A shows the cartridge 804 in a folded, closed or collapsed configuration. In some examples, the cartridge 804 can be inserted into the HMD while in the folded configuration.

FIG. 8B shows a side view of the foldable cartridge 804 in a partially opened configuration and FIG. 8C shows a front view of the cartridge 804 when in an open or unfolded configuration. In some example, inputs 815, 817 can be covered or concealed while the cartridge 804 is in a folded configuration. The inputs 815, 817 can then be uncovered or revealed when the cartridge 804 is opened. In other words, the inputs 815, 817 can be positioned in an interior of the cartridge 804 when the cartridge 804 is folded, and the inputs 815, 817 can be positioned on an exterior of the cartridge 804 when the cartridge 804 is unfolded. In some examples, the first portion 807 can be completely or entirely separated from the second portion 809. The first portion 807 and the second portion 809 can include similar electrical components. For example, both the first portion 807 and the second portion 809 can include a battery, processor, or other components. In some examples, the first portion 807 and the second portion 809 do not share components. For example, the battery may be positioned in the first portion 807 while the processor is positioned in the second portion 809.

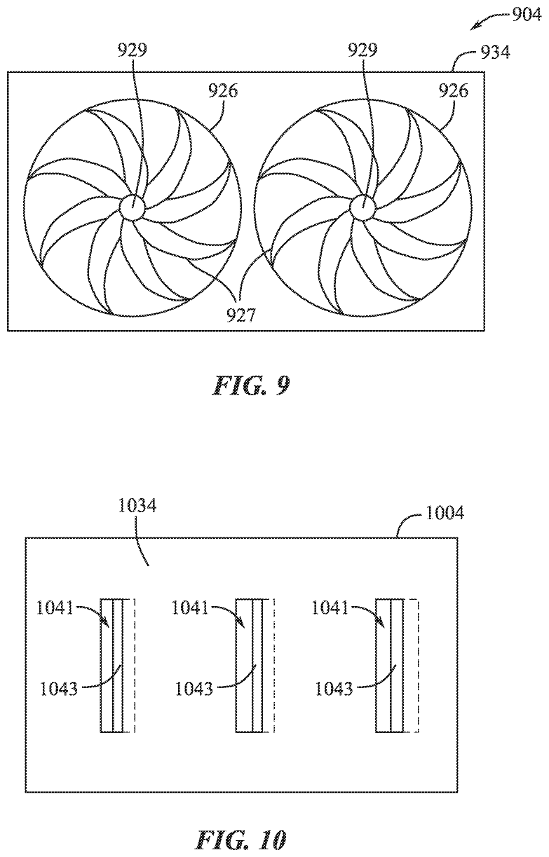

The HMD assembly can include multiple cartridges. In some examples, the assembly includes a primary cartridge (e.g., mother device), and a secondary or companion cartridge (e.g., child device). The primary cartridge and the secondary cartridge can communicate via Bluetooth. In some examples, both the primary cartridge and the secondary cartridge can be attached to or inserted into the HMD. In some examples, the primary cartridge and the secondary cartridge can be attached to each other before being integrated with the HMD. In some examples, the primary cartridge and the secondary cartridge can be independently integrated with the HMD (i.e., separate from each other). Further details regarding the features and functionality of the cartridge are described below with reference to FIG. 9.

Any of the features, components, and/or parts, including the arrangements and configurations thereof shown in FIGS. 8A, 8B, and/or 8C can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIGS. 8A, 8B, and/or 8C.

FIG. 9 shows a top cross-sectional view of a cartridge 904 including fans 926. The cartridge 904 can be substantially similar to, including some or all of the features of, the cartridges described herein, including cartridges 104, 204, 304, 404, 504, 604, 704, and 804.

In some examples, the cartridge 904 can include at least one fan 926. The fan 926 can include one or more blades 927 rotated about a central axis by a motor 929. The fan 926 can generate airflow in/around the cartridge 904 to dissipate heat generated by the electronic components of the cartridge 904 and/or HMD. As illustrated by FIG. 9, the cartridge 904 can include at least two fans 926. The fans 926 can be the same or different sizes. The fans 926 can by positioned symmetrically or asymmetrically relative to one another in the cartridge 904.

FIG. 9 shows the fans 926 uncovered for clarity, however, the fans 926 can be substantially covered by a housing 934 of the cartridge 904. The fans 926 can be in fluid communication with the ambient air outside the cartridge 904 through a vent and/or exhaust in the housing 934. In some example, the fans 926 can function as a haptic engine. For example, the fans 926 can produce a vibration that could be felt by the user as tactile feedback. The blades 927 can be off-center or eccentric such that a vibration is produced as the blades 927 are rotated. In some examples, one of the blades 927 can be more massive or shaped different than the other blades, causing a vibrational output.

In some examples, haptic vibrations can be generated by moving a piece or protrusion into the path of the fans such that the fans impact the piece as they rotate. The repeated impact between the piece and the blades can generate a vibration sensation. The piece can be moved into contact with the fans in response to user input or in response to a status of the media being displayed on the HMD. In some examples, a haptic feedback can be generated by increasing the RPM of the fans.

Further details regarding the cartridge are described below with reference to FIG. 10.

Any of the features, components, and/or parts, including the arrangements and configurations thereof shown in FIG. 9 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 9.

FIG. 10 shows a top view of a cartridge including vents. The cartridge 1004 can be substantially similar to, including some or all of the features of, the cartridges described herein, including cartridges 104, 204, 304, 404, 504, 604, 704, 804, and 904.

In some examples, the cartridge 1004 can include one or more vents 1041 defined by the housing 1034 of the cartridge 1004. The vents 1041 can provide an airflow path between the internals of the cartridge 1004 and the ambient environment. Prevent particle ingress, such as dirt or debris, into the internal volume of the cartridge 1004 is a priority. A challenge exists in allowing for sufficient airflow while preventing particle ingress. To address this challenge, the cartridge 1004 can include doors or shutters 1043 that can move to open or close the vents 1041. In some examples, when the cartridge 1004 is not actively cooling via fans, the shutters 1043 can be closed. The shutters 1043 can then be opened when the cartridge 1004 is actively cooling or venting. In some examples, the shutters 1043 can be electro-mechanically coupled to an actuator that moves the shutters 1043.

In some examples, the position of the shutters 1043 is based on whether the cartridge 1004 is inserted or removed from and HMD. For example, when the cartridge 1004 is in the HMD, particle ingress may be less of a concern because the cartridge 1004 is located in a relatively isolated and sterile environment within the HMD. Further, when the cartridge 1004 is in the HMD, the need for cooling, and therefore the need for the vents 1041 to be open can be greater because of the increased heating caused by the cartridge 1004 being located within the HMD.

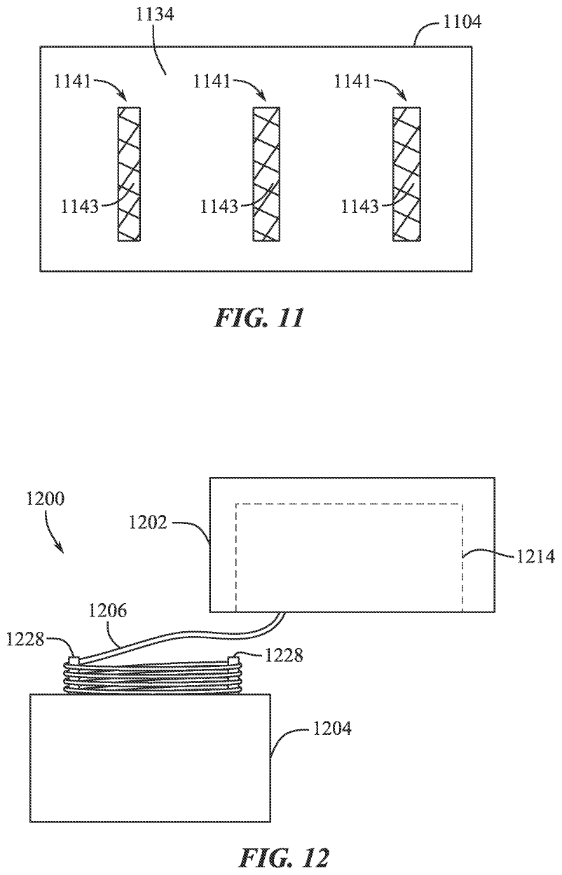

In some examples, the act of inserting the cartridge 1004 into the HMD can cause the shutters 1043 to open. For example, a cam, actuator, or protrusion structurally linked to the shutters 1043 can be engaged by a portion of the HMD, as the cartridge 1004 is inserted into the HMD, thereby causing the shutters 1043 to open. When the cartridge 1004 is removed from the HMD, a similar mechanism, such as a cam or protrusion can engage a component of the HMD to close the vents 1043. In some examples, the vents 1043 are biased (e.g., by a spring) to be in an open or closed configuration. In some example, when the cartridge 1004 is positioned in the HMD, the vents 1043 of the cartridge 1004 can be strategically positioned to align with certain components or airflow pathways in the HMD. Similarly, when the cartridge 1004 is removed from the HMD, additional airflow pathways or vents within the HMD can be opened to allow for increased cooling. Further details regarding the features and functionality of the cartridge are described below with reference to FIG. 11.

Any of the features, components, and/or parts, including the arrangements and configurations thereof shown in FIG. 10 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 10.

FIG. 11 shows a top view of a cartridge including vents. The cartridge 1104 can be substantially similar to, including some or all of the features of, the cartridges described herein, including cartridges 104, 204, 304, 404, 504, 604, 704, 804, 904, and 1004.

In some examples, the cartridge 1104 can include one or more vents 1141 defined by the housing 1134 of the cartridge 1104. The vents 1141 can provide an airflow path between the internals of the cartridge 1104 and the ambient environment. Prevent particle ingress, such as dirt or debris, into the internal volume of the cartridge 1104 is a priority. A challenge exists in allowing for sufficient airflow while preventing particle ingress. To address this challenge, the cartridge 1104 can include a screen or mesh 1143 that can prevents particle ingress while still allowing for airflow. Further details regarding features of HMD assemblies are described below with reference to FIG. 12.

Any of the features, components, and/or parts, including the arrangements and configurations thereof shown in FIG. 11 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 11.

FIG. 12 shows a front view of an HMD assembly 1200 including a cable management system. The HMD assembly 1200 can be substantially similar to, including some or all of the features of, the assemblies described herein, including assemblies 100, 200, 400, 500, and 600.

The HMD assembly 1200 can include an HMD 1202 and a cartridge 1204. The HMD 1202 and the cartridge 1204 can be electrically coupled through a cable 1206. The HMD 1202 can define a recess or slot 1214 defined by the housing of the HMD 1202. As shown in FIG. 12, the outline of the slot 1214 is depicted with dashed lines to indicate that the slot 1214 is positioned in the HMD 1202, for example, between two major surfaces or faces of the HMD. The slot 1214 can be sized and shaped to removably receive the cartridge 1214. The slot 1214 can have a shape the substantially matches the shape of the cartridge 1214.

The cartridge 1204 can include a cable management system for gathering, collecting, or otherwise organizing slack in the cable 1206. In some examples, the cable management system includes one or more posts 1228 about which the cable 1206 can be wound. The slot 1214 can be sized and shaped to accommodate for the cable 1206 as the cartridge 1204 is inserted into the slot 1214. The posts 1228 can be positioned on the cartridge 1204 such that when the cartridge 1204 is inserted into the HMD 1202, the wound cable 1206 in concealed within the HMD 1202. In addition to conveniently storing the slack in the cable 1206, the cable management system also provides pleasing aesthetics by concealing the cable, partially or entirely. The posts 1228 also allow the user to release only the amount of slack that is needed in a particular moment. For example, the cable 1206 might be 10 feet long, however, the user may only need 5 feet of length. Thus, the remaining 5 feet of cable 1206 can remain wound on the posts 1228 where it is less likely to be tangled or in the way of the user. While posts are shown in FIG. 12, it will be understood that other methods of collecting the cable 1206 are envisioned and possible using this method. For example, the cable 1206 can be bunched up and stored in the slot 1214 between the HMD 1202 and the cartridge 1204.

Any of the features, components, and/or parts, including the arrangements and configurations thereof shown in FIG. 12 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 12.

Further details regarding features of HMD assemblies are described below with reference to FIG. 13.

FIG. 13 shows a side cross-sectional view of a head-mountable system including a cable management system. The HMD assembly 1300 can be substantially similar to, including some or all of the features of, the assemblies described herein, including assemblies 100, 200, 400, 500, 600, and 1200.

The HMD assembly 1300 can include a removable or deployable cartridge 1304, as described herein. The HMD 1302 can include a frame or housing 1347 that defines one or more openings 1314 through which the cartridge 1304 can be inserted into or removed from the HMD 1302.

The cartridge 1304 can include a coupling member 1330 to engage with a corresponding coupling member 1316 on the HMD 1302. The coupling members 1330, 1316 can include any suitable mechanical attachment mechanism, including clips, fasteners, threads, detents, protrusions, etc. In some examples, the coupling members 1330, 1316 form a push-push mechanism to release and attached the cartridge 1304. In some examples, the coupling member 1330 can include a magnet or magnetically attracted component located on an exterior or interior of the cartridge 1304. Likewise, the coupling member 1316 can include a magnet or magnetically attracted component positioned to magnetically couple with the coupling member 1330 of the cartridge 1304, when the cartridge is inserted into the HMD 1302. In some examples, the coupling member 1316 can be secured to the HMD 1302, such as mounted to the housing 1347. In some examples, the cartridge 1304 and the HMD 1302 can each include multiple magnets to secure the cartridge 1304 within the HMD 1302. The strength of the magnets 1316, 1330 can be selected or tuned to be strong enough to securely retain the cartridge 1304 within the HMD 1302 when experiencing typical movement of the HMD 1302, yet weak enough to be overcome by a user to remove the cartridge 1304.

In some examples, the HMD assembly 1300 includes electrical connectors 1316, 1330. When the cartridge 1304 is positioned in the HMD 1302, electrical terminals or contacts 1330 on the cartridge 1304 can electrically engage corresponding contacts 1316 in the HMD 402 to establish an electrical connection to transmit data and/or power. To establish a connected between the HMD 1302 and the inserted cartridge 1304, any suitable plug for establishing a data connect can be used, including a USB connector, HMDI connector, DisplayPort connector, VGA connector, etc. It will be understood that by having an electrical connection for the inserted cartridge 1304 to connect to the HMD 1302, the cable 1306 can be removed. In some examples, the respective cable connection interfaces on the cartridge 1304 and the HMD 1302 are configured to engage with each other when the cable 1306 is removed.

In some examples, when inserted into the HMD 1302, the cartridge 1304 can be positioned or sandwiched between the display 1345 and other electronic components or the front face of the HMD 1302. As described herein, the cartridge 1304 can include cooling fans to produce air flow to lower the temperature of the internals of the cartridge 1304 and/or the internals of the HMD 1302. In some examples, the cartridge 1304 can be intentionally positioned to allow for ideal airflow to the internal components of the HMD 1302 when inserted, and allow for ideal passive airflow or “breathing” for the HMD 1302 when the cartridge 1304 is removed.

The cartridge 1304 can include a cable management system. For example, the cartridge 1304 can include one or more posts 1328. The posts 1328 can be located on any side or surface of the cartridge 1304. In the example of FIG. 13, the posts 1328 are shown on a side of the cartridge 1304 (as oriented in FIG. 13). As illustrated, upon winding the cable 1306 and inserting the cartridge 1304 into the HMD 1302, the cable 1306 can substantially or entirely be positioned or concealed within the HMD 1302.

Any of the features, components, and/or parts, including the arrangements and configurations thereof shown in FIG. 13 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 13.

To the extent applicable to the present technology, gathering and use of data available from various sources can be used to improve the delivery to users of invitational content or any other content that may be of interest to them. The present disclosure contemplates that in some instances, this gathered data may include personal information data that uniquely identifies or can be used to contact or locate a specific person. Such personal information data can include demographic data, location-based data, telephone numbers, email addresses, TWITTER® ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of advertisement delivery services, the present technology can be configured to allow users to select to “opt in” or “opt out” of participation in the collection of personal information data during registration for services or anytime thereafter. In another example, users can select not to provide mood-associated data for targeted content delivery services. In yet another example, users can select to limit the length of time mood-associated data is maintained or entirely prohibit the development of a baseline mood profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, content can be selected and delivered to users by inferring preferences based on non-personal information data or a bare minimum amount of personal information, such as the content being requested by the device associated with a user, other non-personal information available to the content delivery services, or publicly available information.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not target to be exhaustive or to limit the embodiments to the precise forms disclosed. It will be apparent to one of ordinary skill in the art that many modifications and variations are possible in view of the above teachings.

What is claimed is:

1. A cartridge, comprising:
a housing;
a processor positioned within the housing, the processor configured to provide video output to a display unit of a head-mounted display (HMD); and
an attachment interface configured to removably attach the cartridge to the display unit.

2. The cartridge of claim 1, further comprising:
a battery positioned within the housing, the battery configured to power the HMD; and
a cable electrically connecting the cartridge to the HMD;
wherein the cartridge is configured to be removably inserted into a slot defined by the HMD.

3. The cartridge of claim 1, wherein the attachment interface is configured to removably attach the cartridge within an internal volume of the display unit.

4. The cartridge of claim 1, further comprising a fan positioned within the housing, wherein, when the cartridge is attached to the HMD, the fan is positioned proximate a component disposed in an internal volume of the HMD and is configured to provide an airflow to the internal volume.

5. The cartridge of claim 1, wherein the attachment interface comprises at least one of a mechanical coupler or a magnetic coupler.

6. The cartridge of claim 1, wherein the attachment interface comprises a push-push mechanism.

7. The cartridge of claim 1, further comprising a user input interface to receive a user input.

8. A head-mountable assembly, comprising:
a processor; and
a display unit defining a slot to receive the processor;
wherein:
in a first mode, the processor is positioned within the slot and configured to provide image data to the display unit; and
in a second mode, the processor is removed from the slot and is configured to provide image data to the display unit.

9. The head-mountable assembly of claim 8, wherein the processor is positioned adjacent to a display screen of the display unit in the first mode.

10. The head-mountable assembly of claim 8, wherein, in the second mode, the processor is secured to a retention band of the display unit.

11. The head-mountable assembly of claim 8, further comprising a coupler to releasably secure the processor in the slot.

12. The head-mountable assembly of claim 8, further comprising a biasing element to selectively retain the processor in the display unit.

13. The head-mountable assembly of claim 8, further comprising a cable electrically connecting the processor and the display unit in the second mode.

14. The head-mountable assembly of claim 8, further comprising a first electrical connector positioned in the slot and configured to engage a second electrical connector on the processor in the first mode.

15. An electronic component for a head-mountable device, the electronic component comprising:
an input to receive a user input; and
a central processing unit (CPU) of the head-mountable device;
wherein the electronic component is configured to be selectively carried by the head-mountable device.

16. The electronic component of claim 15, wherein the input comprises at least one of a button, a touchpad, or an analog stick, or a D-pad.

17. The electronic component of claim 15, further comprising a haptic engine.

18. The electronic component of claim 15, wherein the electronic component is attachable to the head-mountable device.

19. The electronic component of claim 15, further comprising a motion sensor to provide user feedback to the CPU.

20. The electronic component of claim 15, further comprising a battery, wherein the battery is a primary power source of the head-mountable device.
